(19) United States
(12) Patent Application Publication
(10) Pub. No.: US 2025/0065471 A1
(43) Pub. Date: Feb. 27, 2025

(54) DRESSER FOR POLISHING PAD, DRESSING METHOD, POLISHING METHOD, AND METHOD FOR MANUFACTURING WORKPIECE

(71) Applicant: NORITAKE CO., LIMITED, Nagoya-shi, Aichi (JP)

(72) Inventors: Masatoshi KISHIMOTO, Nagoya-shi, Aichi (JP); Takehiro SUZUKI, Nagoya-shi, Aichi (JP)

(21) Appl. No.: 18/724,774

(22) PCT Filed: Nov. 30, 2022
(86) PCT No.: PCT/JP2022/044300

§ 371 Date: Jun. 27, 2024

(30) Foreign Application Priority Data
Jan. 5, 2022 (JP) 2022-000415

(51) Int. Cl. B24B 53/017; B24B 53/12

(52) U.S. Cl. CPC B24B 53/017; B24B 53/12

(57) ABSTRACT

Provided is a novel dresser that can impart higher flatness to a polishing pad. A dresser for a polishing pad surface, the dresser including: a dressing surface having a circular shape with a diameter DCD and facing the pad surface, and pellets arranged on the dressing surface, in which the pellets are arranged in circumferential regions with a diameter PCDn, in which the circumferential regions share a center of the dressing surface; and an area ratio of the pellets arranged in each circumferential region is any one of predetermined Type 1, Type 2, and Type 3.

### TECHNICAL FIELD

This invention relates to a dresser for a polishing pad.

### BACKGROUND ART

A dresser for a polishing pad (hereinafter, sometimes simply abbreviated as “dresser”) is required to have a function of flatly polishing a pad serving as a polishing target.

Therefore, various measures have been conventionally taken (see Patent Literatures 1 to 3).

The dresser includes a pellet and a holding member supporting the pellet, and the pellet is arranged at a predetermined position on a surface (dressing surface) of the holding member facing the pad.

It is common to arrange pellets at equal intervals on a concentric circle from a rotation center of the dressing surface (see Patent Literature 1). In Patent Literature 2, flat polishing on the pellet is ensured by defining a relationship on a circular dressing surface between a radius of the dressing surface and a particle size of a pellet.

In addition, as citations related to the invention of the present application, refer to Patent Literature 3 and Patent Literature 4.

### CITATIONS LIST

### Patent Literature

Patent Literature 1: JP 2000-141204 A
Patent Literature 2: JP 5809880 B2
Patent Literature 3: JP 2006-55944 A
Patent Literature 4: JP 5511266 B2

### SUMMARY OF INVENTION

### Technical Problems

The polishing target of a polishing pad is exclusively a semiconductor substrate, and the semiconductor substrate is required to have higher flatness with miniaturization of the semiconductor element formed thereon. For this reason, the polishing pad is also required to have higher flatness. Therefore, the dresser is also required to have a function of more flattening the polishing pad.

### Solutions to Problems

As a result of intensive studies to solve the above problems, the present inventors have found a preferred relationship between the area and arrangement of pellets with respect to the dressing surface.

That is, the first aspect of this invention is defined as follows.

A dresser for polishing a pad surface, the dresser including:
a dressing surface having a circular shape with a diameter DCD and facing the pad surface, and pellets arranged on the dressing surface, wherein
the pellets are arranged in circumferential regions with a diameter PCDn, wherein the circumferential regions share a center of the dressing surface; and
an area ratio of the pellets arranged in each circumferential region is any one of Type 1, Type 2, and Type 3 in Table 1 below.

TABLE 1

| | PCDn | PCDn/DCD = Rn (%) | Pellet area ratio (%) |
|---|---|---|---|
| Type 1 | PCD5 | 0 < R5 ≤ 20 | 0 |
| | PCD4 | 20 < R4 ≤ 40 | 30 ± 5 |
| | PCD3 | 40 < R3 ≤ 60 | 45 ± 5 |
| | PCD2 | 60 < R2 ≤ 80 | 10 ± 5 |
| | PCD1 | 80 < R1 < 100 | 15 ± 5 |
| Type 2 | PCD5 | 0 < R5 ≤ 20 | 0 |
| | PCD4 | 20 < R4 ≤ 40 | 25 ± 3 |
| | PCD3 | 40 < R3 ≤ 60 | 25 ± 3 |
| | PCD2 | 60 < R2 ≤ 80 | 25 ± 3 |
| | PCD1 | 80 < R1 < 100 | 25 ± 3 |
| Type 3 | PCD5 | 0 < R5 ≤ 20 | 0 |
| | PCD4 | 20 < R4 ≤ 40 | 40 ± 3 |
| | PCD3 | 40 < R3 ≤ 60 | 31 ± 3 |
| | PCD2 | 60 < R2 ≤ 80 | 20 ± 3 |
| | PCD1 | 80 < R1 < 100 | 9 ± 3 |

According to the dresser of the first aspect defined in this manner, the polishing pad can be polished flat. In particular, a recess of center side of the polishing pad can be effectively prevented.

According to the dresser that can impart high flatness to the polishing pad, it is possible to shorten the dressing time for the polishing pad, and thus, in this respect, it is possible to contribute to improvement of throughput in the manufacturing process of a semiconductor substrate and the like. Furthermore, shortening of the dressing time and high flatness improve the life of the polishing pad itself, and also in this respect, it is possible to contribute to improvement of throughput in the manufacturing process of a semiconductor substrate and the like.

According to the study of the present inventors, even if the dresser defined in the first aspect is driven with respect to the polishing pad at the time of dressing, that is, even if the dresser is caused to co-rotate with respect to the polishing pad, the dresser exhibits that effect. The same applies to a case where rotation of the dresser can be controlled.

### BRIEF DESCRIPTION OF DRAWINGS

FIGS. 1A-1C are schematic views illustrating a relationship among a dresser of an embodiment of this invention, pellets, and a polishing pad.

FIGS. 2A-2E illustrate an arrangement mode of the pellets on a dressing surface of the dresser defined in Table 1.

FIGS. 3A-3C a polishing result (FIG. 3B) of a pad by a dresser (FIG. 3A) of Example 1 and a trajectory density (FIG. 3C, simulation result) of the pellets.

FIGS. 4A-4C illustrate a polishing result (FIG. 4B) of a pad by a dresser (FIG. 4A) of Comparative Example 1 and a trajectory density (FIG. 4C, simulation result) of the pellets.

FIGS. 5A and 5B illustrate arrangement modes of pellets on dressing surfaces of dressers of embodiments of other Examples 2 to 5 included in Type 1 and trajectory densities of the pellets.

FIGS. 6A-6B illustrate arrangement modes of pellets on dressing surfaces of dressers of Examples 6 and 7 and trajectory densities of the pellets.

FIGS. 7A-7B illustrate an arrangement mode of pellets on a dressing surface of a dresser of Comparative Example 2 and a trajectory density of the pellets.

FIG. 8 illustrates an arrangement mode of pellets on the dressing surface of the dresser of Example 1 and a density distribution in each grid of an imaginary mesh applied to the dressing surface.

FIG. 9 illustrates an arrangement mode of pellets on the dressing surface of the dresser of Example 2 and a density distribution in each grid of an imaginary mesh applied to the dressing surface.

FIG. 10 illustrates an arrangement mode of pellets on the dressing surface of the dresser of Example 3 and a density distribution in each grid of an imaginary mesh applied to the dressing surface.

FIG. 11 illustrates an arrangement mode of pellets on the dressing surface of the dresser of Example 4 and a density distribution in each grid of an imaginary mesh applied to the dressing surface.

FIG. 12 illustrates an arrangement mode of pellets on the dressing surface of the dresser of Example 5 and a density distribution in each grid of an imaginary mesh applied to the dressing surface.

FIG. 13 illustrates an arrangement mode of pellets on the dressing surface of the dresser of Example 6 and a density distribution in each grid of an imaginary mesh applied to the dressing surface.

FIG. 14 illustrates an arrangement mode of pellets on the dressing surface of the dresser of Example 7 and a density distribution in each grid of an imaginary mesh applied to the dressing surface.

FIG. 15 illustrates an arrangement mode of pellets on the dressing surface of the dresser of Comparative Example 2 and a density distribution in each grid of an imaginary mesh applied to the dressing surface.

FIG. 16 is a graph showing a comparison between the number of times of polishing and the polishing rate for an LHA polishing pad when the dresser of Example 1 and the dresser of Comparative Example 1 are used.

### DESCRIPTION OF EMBODIMENT

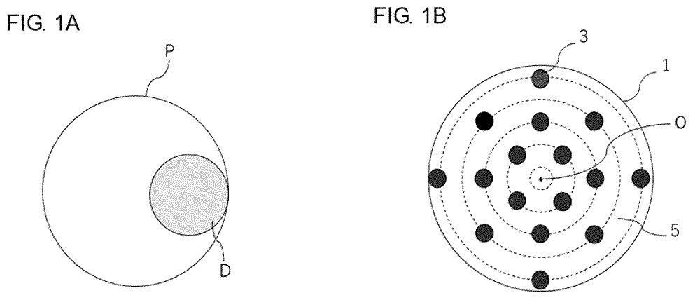

FIGS. 1A-1B are schematic views illustrating a relationship among a dresser of an embodiment, pellets, and a polishing pad.

FIG. 1A illustrates a positional relationship between a polishing pad P and a dresser D in dressing work. In the dressing work, the polishing pad P is rotated about the center thereof by a driving device not illustrated. In this example, the center of the dresser D is rotatably pivotally supported by a support shaft not illustrated and abuts on the polishing pad P, and follows rotation of the polishing pad P and is co-rotated.

It is also possible to control rotation of the dresser D independently of rotation of the polishing pad P by attaching the dresser D to a shaft to be rotationally driven.

The diameter (sometimes simply called “diameter” in this description) of the outer periphery and the material of the polishing pad P can be arbitrarily selected in accordance with the polishing target. For the semiconductor substrate, for example, the diameter of the polishing pad P can be Φ 300 to 1500 mm, and the material thereof can include rigid polyurethane, nonwoven fabric, and suede.

The rotation number of the polishing pad P in the dressing work can be arbitrarily selected in accordance with the diameter of the dresser D, the material of the pellets, the pressure of the dresser D, and the like.

With respect to the polishing pad P (diameter Φ 300 to 1500 mm) for a semiconductor substrate, the rotation number at the time of dressing work can be 5 to 100 rpm.

The polishing pad P is fixed to a turntable of a general-purpose polishing device.

The dresser D includes a holding member 1 and a pellet 3.

The holding member 1 is a disk-shaped member, and the center of one surface is rotatably pivotally supported by a shaft. The other surface facing the polishing pad P becomes a pellet support surface 5 (see FIG. 1) B.

A plurality of the pellets 3 are distributed and fixed to this pellet support surface 5 in accordance with a predetermined rule.

The dressing surface is a surface that acts on the polishing pad P, and from the viewpoint, the dressing surface should be defined by a circumference drawn by the pellet existing outermost (outer edge thereof). In this example, the outer peripheral edge of the holding member 1 and the outermost pellet 3 substantially coincide with each other. As a result, the pellet support surface 5 and the dressing surface coincide with each other. Note that the diameter of the free end (the diameter when the free end is approximated to a circle) of the pellet 3 abutting on the polishing pad P is extremely small as compared with the diameter of the dressing surface, and therefore, in this description, the description will proceed with the pellet support surface 5 having a circular shape as the dressing surface.

The rotation center of a dressing surface 5 coincides with the rotation center of the holding member 1.

It is possible to use the pellet 3 in which hard particles are supported on a base. The base is, for example, a steel material having a columnar shape, hard particles are supported on a free end side thereof, and the other end side thereof is fixed to the pellet support surface 5 by a general-purpose method such as brazing. In this example, the free end of the base is circular, and the hard particles are evenly distributed and fixed thereto. The diameter of the free end can be Φ 5 to 30 mm. This free end can also be elliptical or polygonal.

The hard particles are not particularly limited as long as they can polish and dress the polishing pad P, but general-purpose materials such as diamond, boron nitride, boron carbide, silicon carbide, and aluminum oxide are adopted.

The mean particle size of the hard particles can also be arbitrarily selected, and for example, diamond having a mean particle size of 0.1 to 250 μm can be adopted.

The hard particles are fixed to the free end of the base using an epoxy-based adhesive, wax, or the like.

In the schematic view of FIG. 1B, five circumferences are drawn by dotted lines in the radial direction from a rotation center O of the dressing surface 5. The center of the free end of the pellet 3 is arranged on this dotted line, and each pellet 3 is evenly distributed in the circumferential direction. The circumference represented by this dotted line can vary in the radial direction (circumferential region).

In the first embodiment (Type 1), the area ratio of the pellets 3 arranged in the circumferential region of the diameter PCDn sharing the center O with respect to the diameter DCD of the dressing surface 5 is defined as shown in Table 2.

TABLE 2

| | PCDn | PCDn/DCD = Rn (%) | Pellet area ratio (%) |
|---|---|---|---|
| Type 1 | PCD5 | 0 < R5 ≤ 20 | 0 |
| | PCD4 | 20 < R4 ≤ 40 | 30 ± 5 |
| | PCD3 | 40 < R3 ≤ 60 | 45 ± 5 |
| | PCD2 | 60 < R2 ≤ 80 | 10 ± 5 |
| | PCD1 | 80 < R1 < 100 | 15 ± 5 |

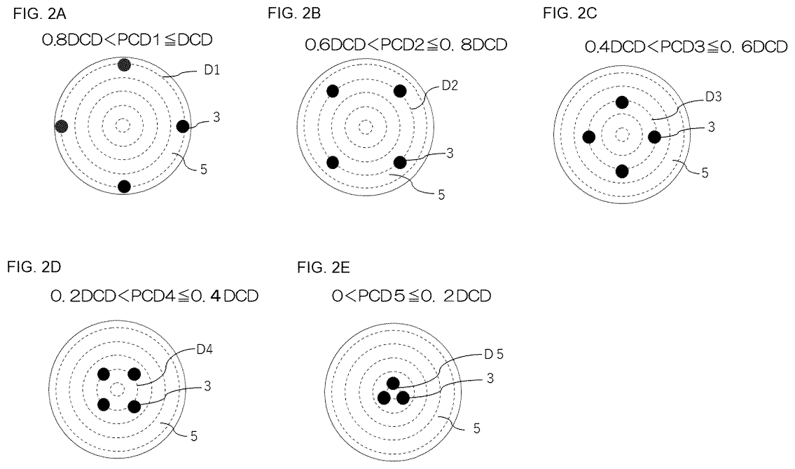

Each value in Table 2 will be described in detail with reference to FIG. 2.

FIG. 2A illustrates pellets arranged in a circumferential region of a diameter PCD1. That is, the centers of the pellets 3 are arranged in the circumferential region indicated by a dotted line D1 in FIG. 2A with respect to the diameter DCD of the dressing surface 5. The circumferential region of the diameter PCD1 has a width of PCD1/DCD=80 to 100%.

In Table 2, the area ratio of the free ends of the pellets 3 arranged on the circumferential region of the diameter PCD1 is 15±5%.

This area ratio is defined as follows.

It is a ratio of the total area of the free ends of the pellets 3 existing in the circumferential region of the diameter PCD1 to the total area of the free ends of all the pellets 3 existing in the dressing surface 5. Hereinafter, the area ratio is similarly calculated in other circumferential regions.

FIG. 2B illustrates pellets arranged in a circumferential region of a diameter PCD2. That is, the centers (referring to the centers of the free ends, and the same in this description) of the pellets 3 are arranged in the circumferential region indicated by a dotted line D2 in FIG. 2B with respect to the diameter DCD of the dressing surface 5. The circumferential region of the diameter PCD2 has a width of PCD2/DCD=60 to 80%.

In Table 2, the area ratio of the free ends of the pellets 3 arranged on the circumferential region of the diameter PCD2 is 10±5%.

FIG. 2C illustrates pellets arranged in a circumferential region of a diameter PCD3. That is, the centers of the pellets 3 are arranged in the circumferential region indicated by a dotted line D3 in FIG. 2C with respect to the diameter DCD of the dressing surface 5. The circumferential region of the diameter PCD3 has a width of PCD3/DCD=40 to 60%.

In Table 2, the area ratio of the free ends of the pellets 3 arranged on the circumferential region of the diameter PCD3 is 45±5%.

FIG. 2D illustrates pellets arranged in a circumferential region of a diameter PCD4. That is, the centers of the pellets 3 are arranged in the circumferential region indicated by a dotted line D4 in FIG. 2D with respect to the diameter DCD of the dressing surface 5. The circumferential region of the diameter PCD4 has a width of PCD4/DCD=20 to 40%.

In Table 2, the area ratio of the free ends of the pellets 3 arranged on the circumferential region of the diameter PCD4 is 30±5%.

FIG. 2E illustrates pellets arranged in a circumferential region of a diameter PCD5. That is, the centers of the pellets 3 are arranged in the circumferential region indicated by a dotted line D5 in FIG. 2E with respect to the diameter DCD of the dressing surface 5. The circumferential region of the diameter PCD5 has a width of PCD5/DCD=0 to 20%.

In Table 2, the area ratio of the free ends of the pellets 3 arranged on the circumferential region of the diameter PCD5 is 0%.

In the above example, the pellets are evenly arranged in the circumferential direction in each circumferential region, but this is not always necessary. For example, they can be arranged point-symmetrically in each circumferential region about the rotation center O.

Furthermore, it is also possible to arrange the pellets so that the centers of gravity of the free ends of the pellets existing in an identical circumferential region coincide with the rotation center by satisfying the conditions in Table 2.

Each of the circumferential regions PCD1 to 5 has a width. Within each width, the center of the pellet can be shifted radially. When the arrangement of the pellets 3 is dispersed in the radial direction of the dressing surface 5 in this manner, it is preferable that the centers of gravity of the free ends of all the pellets 3 coincide with the rotation center of the dressing surface 5.

The area of the free end of each pellet can be given a change within a range satisfying the pellet area ratio shown in Table 2.

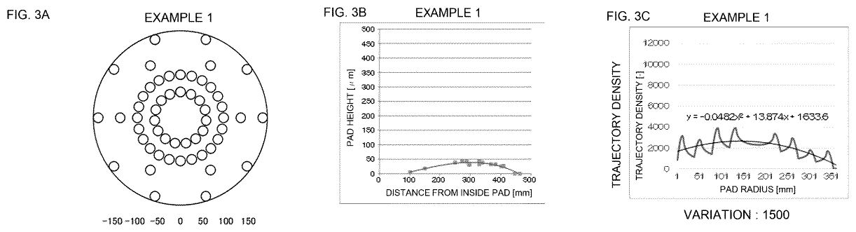

As a dresser (Example 1) satisfying the conditions of Table 2, the following was prepared (see FIG. 3A). Note that the diameter of the dressing surface is Φ 360 mm, and the diameter of the circular free end of each pellet 3 abutting on the polishing pad P is Φ 16 mm.

TABLE 3

| | PCDn | | | | Pellet |
|---|---|---|---|---|---|
| Example | | Diameter | PCDn/DCD | Number | area ratio |
| 1 | | mm | (%) | of pellets | (%) |
| Type 1 | PCD5 | | | | |
| | PCD4 | 100 | 28% | 15 | 27 |
| | PCD3 | 180 | 50% | 24 | 44 |
| | PCD2 | 260 | 72% | 6 | 11 |
| | PCD1 | 340 | 94% | 10 | 18 |

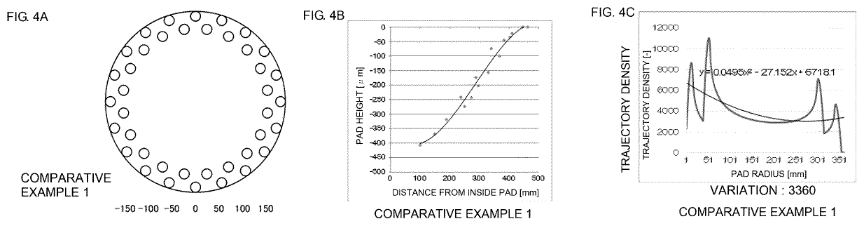

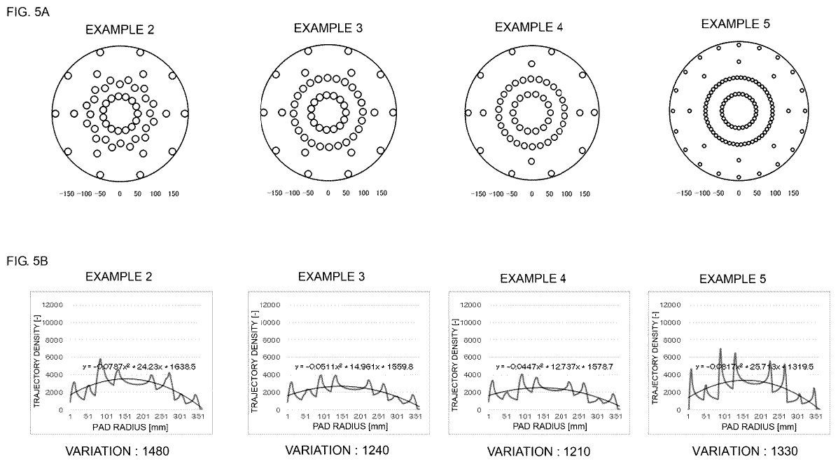

As Comparative Example 1, a dresser under the conditions of Table 4 was prepared (see FIG. 4A). The diameter of the dressing surface and the shape of each pellet 3 are the same as those in Example 1.

TABLE 4

| | | | | | Pellet |
|---|---|---|---|---|---|
| | PCDn | | | | area |
| Comparative | | Diameter | PCDn/DCD | Number of | ratio |
| Example 1 | | mm | (%) | pellets | (%) |
| | PCD5 | | | | |
| | PCD4 | | | | |
| | PCD3 | | | | |
| | PCD2 | 260 | 72% | 20 | 50 |
| | PCD1 | 340 | 94% | 20 | 50 |

Using each of the dressers of Example 1 and Comparative Example 1, dressing of the polishing pad was performed under the same conditions. The results are illustrated in FIGS. 3B and 4B. The thickness variation of the polishing pad surface in Example 1 was 50 μm, and that in Comparative Example 1 was 400 μm. Note that the variation in the thickness of the polishing pad surface is a difference in thickness between the most polished portion (thinnest portion) and the least polished portion (thickest portion) on the polishing pad surface.

The conditions of the dressing were as follows.
Pad diameter: 920 mm
Pad rotation number: 35 rpm
Dresser rotation number: about 30 rpm (co-rotation)
Dress pressure: 30 kPa
Dresser position: 272 mm
Dressing time: performed for 30 seconds/time×60 times (30 minutes in total)
Pellet material: metal diamond grindstone
Polishing device used: Fujikoshi Machinery Corp., SPM 14

The shape of the surface of the polishing pad (the position in the radial direction and the height thereof) was measured using a dial gauge.

The results of FIGS. 3B and 4B indicate that according to the dressing using the dresser of Comparative Example 1, the polishing pad is polished so as to be recessed on the center side, whereas according to the dresser of Example 1, such a recess is not seen, and the polishing pad is polished extremely flat.

The inventors of the present application considered that the difference between the dresser of the example and the dresser of the comparative example was caused by the frequency of pellets interfering with the polishing pad when performing the dressing work.

Therefore, the trajectory of each pellet with respect to the polishing pad when the dressing was performed under the above conditions was simulated, and the density of the trajectory of the pellet passing through an imaginary line in the radial direction from the center of the polishing pad was calculated. The result of Example 1 is illustrated in FIG. 3C. In FIG. 3C, the thick line indicates the trajectory density, and the thin line is an approximate curve thereof. The trajectory density indicates the degree of overlap with the pellet trajectory with respect to the pad surface. The approximate curve of the trajectory density is approximated by a second-order polynomial.

The approximate curve in FIG. 3C is expressed by

$$y = - 0.0482 {x}^{2} + 13.874 x + 1633.6 .$$

Similarly, the approximate curve in FIG. 4C is expressed by

$$y = 0.0495 {x}^{2} - 27.152 x + 6718.1 .$$

The variation of the trajectory density in FIG. 3C was 1500. This variation indicates a difference between the maximum value and the minimum value of the approximate curve.

The result of FIG. 3C indicates that in the dresser of Example 1, the pellets substantially evenly interfere with the entire polishing pad. The approximate curve indicates that the trajectory density is high (the approximate curve exhibits the maximum value) between the center and the outer edge of the polishing pad (the center of the imaginary line), and the interference frequency therein is high.

The same simulation as in the example is performed for the dresser of Comparative Example 1, and the result is illustrated in FIG. 4C.

The result of FIG. 4C indicates that interference of the pellets with respect to the polishing pad is unevenly distributed in the dresser of Comparative Example 1. In particular, the trajectory density of the pellet becomes high on the center side of the polishing pad.

The variation of the trajectory density was 3360.

From the result of FIG. 3C and the result of FIG. 4C, it is expected that the polishing pad can be polished flat if the variation in trajectory density becomes equal to or less than a predetermined value.

The present inventors also created a dresser satisfying the conditions in Table 2 (see Examples 2 to 5 and FIGS. 5A-5B, and the size and shape of the dressing surface and the pellet in Examples 2 to 4 are the same as those in Example 1. In Example 5, the diameter of the free end of the pellet is Φ 8 mm). FIG. 5A schematically illustrates an arrangement mode of pellets with respect to the dressing surface of the dresser of each Example. The trajectory of each pellet was simulated in accordance with FIG. 3C, and the density of the trajectories of the pellets passing through the imaginary line in the radial direction from the center of the polishing pad was calculated. The results are illustrated in FIG. 5B. It is indicated that the variation in trajectory density is small also in the dressers of Examples 2 to 5. The maximum value of the approximate curve of the trajectory density exists between the center and the outer edge of the polishing pad. In other words, the approximate curve along the imaginary line becomes convex.

The approximate curves according to Examples 2 to 5 are expressed as follows.

$$Example 2 y = - 0.0787 {x}^{2} + 24.23 x + 1638.5$$

$$Example 3 y = - 0.0511 {x}^{2} + 14.961 x + 1559.8$$

$$Example 4 y = - 0.0447 {x}^{2} + 12.737 x + 1578.7$$

$$Example 5 y = - 0.0817 {x}^{2} + 25.713 x + 1819.5$$

Using variations in the trajectory density and/or the shape of the approximate curve of the trajectory density as an index, the present inventors have also studied those whose arrangement mode of the pellet deviates from the conditions in Table 2.

As a result, also in the dressers (Examples 6 and 7) under the conditions Type 2 and Type 3 shown in Table 5, variation of the trajectory density that is low, (i.e., equal to or less than 2000) and the maximum value of the approximate curve of the trajectory density exist between the center and the outer edge of the polishing pad.

TABLE 5

| | | | | | Pellet |
|---|---|---|---|---|---|
| | PCDn | | | | area |
| | | Diameter | PCDn/DCD | Number | ratio |
| | | mm | (%) | of pellets | (%) |
| Example 6 | | | | | |
| Type 2 | PCD5 | | | | |
| | PCD4 | 100 | 28% | 10 | 25 |
| | PCD3 | 180 | 50% | 10 | 25 |
| | PCD2 | 260 | 72% | 10 | 25 |
| | PCD1 | 340 | 94% | 10 | 25 |
| Example 7 | | | | | |
| Type 3 | PCD5 | | | | |
| | PCD4 | 100 | 28% | 18 | 40 |
| | PCD3 | 180 | 50% | 14 | 31 |
| | PCD2 | 260 | 72% | 9 | 20 |
| | PCD1 | 340 | 94% | 4 | 9 |

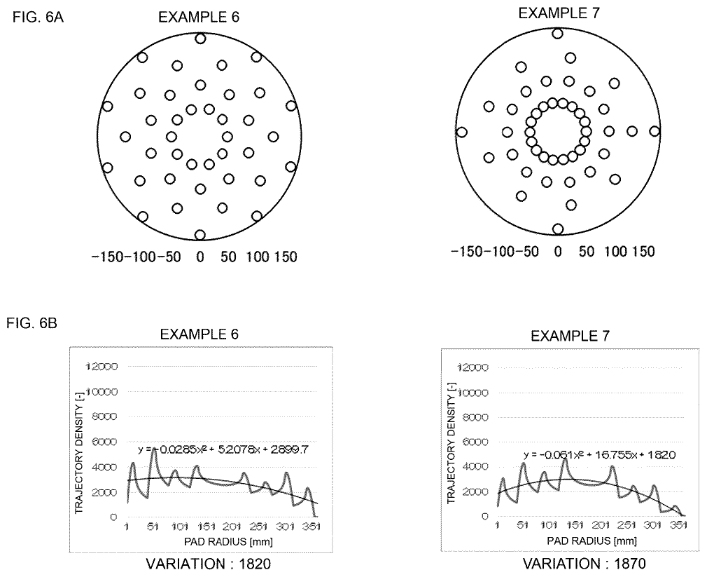

FIG. 6A schematically illustrates arrangement modes of pellets with respect to the dressing surfaces of the dressers of Examples 6 and 7. The density of the trajectories of the pellets passing through the imaginary line in the radial direction from the center of the polishing pad when the dressers of Examples 6 and 7 are used were calculated and illustrated in FIG. 6B.

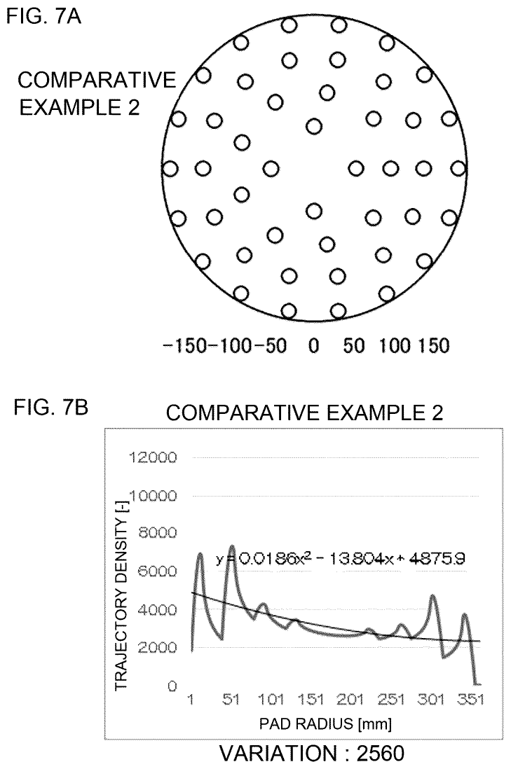

On the other hand, in the dresser of Comparative Example 2 having the relationship presented in Table 6 and FIGS. 7A-7B, the variation in the trajectory density exceeded 2000, and the maximum value of the approximate curve of the trajectory density existed in the center part of the polishing pad.

TABLE 6

| | | | | | Pellet |
|---|---|---|---|---|---|
| | PCDn | | | Number | area |
| | | Diameter | PCDn/DCD | of | ratio |
| | | mm | (%) | pellets | (%) |
| Comparative | PCD5 | | | | |
| Example 2 | PCD4 | 100 | 28% | 4 | 9 |
| | PCD3 | 180 | 50% | 9 | 20 |
| | PCD2 | 260 | 72% | 14 | 31 |
| | PCD1 | 340 | 94% | 18 | 40 |

The approximate curve of Comparative Example 2 is expressed as follows.

$$Y = 0.0186 {x}^{2} - 13.804 x + 4875.9$$

Example 6 suggests that according to the dresser satisfying the relationship of Type 2 in Table 7 below, the polishing pad can be dressed extremely flat.

Example 7 suggests that according to the dresser satisfying the relationship of Type 3 in Table 7 below, the polishing pad can be dressed extremely flat.

TABLE 7

| | PCDn | PCDn/DCD = Rn (%) | Pellet area ratio (%) |
|---|---|---|---|
| Type 2 | PCD5 | 0 < R5 ≤ 20 | 0 |
| | PCD4 | 20 < R4 ≤ 40 | 25 ± 3 |
| | PCD3 | 40 < R3 ≤ 60 | 25 ± 3 |
| | PCD2 | 60 < R2 ≤ 80 | 25 ± 3 |
| | PCD1 | 80 < R1 < 100 | 25 ± 3 |
| Type 3 | PCD5 | 0 < R5 ≤ 20 | 0 |
| | PCD4 | 20 < R4 ≤ 40 | 40 ± 3 |
| | PCD3 | 40 < R3 ≤ 60 | 31 ± 3 |
| | PCD2 | 60 < R2 ≤ 80 | 20 ± 3 |
| | PCD1 | 80 < R1 < 100 | 9 ± 3 |

As described above, according to the dresser defined as the first aspect of this invention, the polishing pad can be dressed flat.

In particular, according to the dresser of Type 1 that can suppress variation in trajectory density in the polishing pad to equal to or less than 1500, flatness can be further improved.

From the comparison of the trajectory densities of pellets in Examples and Comparative Examples, another aspect of this invention can be defined as follows.

A dresser for a polishing pad surface, the dresser including:
a dressing surface facing the pad surface and pellets arranged on the dressing surface,
when the pad surface is rotated about a center of the pad surface as an axis and the dressing surface itself is rotated about the center as an axis, a variation in trajectory density of the pellets passing through an imaginary line in a radial direction from the center of the pad surface becomes equal to or less than 2000 or less, preferably equal to or less than 1500.

Furthermore, it can also be defined as follows.

A dressing method for dressing a pad surface by a dresser for the polishing pad surface, including:
a dressing surface facing the pad surface and pellets arranged on the dressing surface, the dressing method, wherein
when the pad surface is rotated about a center of the pad surface as an axis and the dressing surface itself is rotated about the center as an axis, a variation in trajectory density of the pellets passing through an imaginary line in a radial direction from the center of the pad surface is made equal to or less than 2000 or less, preferably equal to or less than 1500.

Furthermore, this invention can also be defined as follows.

A dresser for a polishing pad surface, the dresser including:
a dressing surface facing the pad surface and pellets arranged on the dressing surface,
when the pad surface is rotated about a center of the pad surface as an axis and the dressing surface itself is rotated about the center as an axis, an approximate curve along an imaginary line of distribution in trajectory density of the pellets passing through the imaginary line in a radial direction from the center of the pad surface becomes convex.

Furthermore, this invention can also be defined as follows.

A dressing method for dressing a pad surface by a dresser for the polishing pad surface, including:
a dressing surface facing the pad surface and pellets arranged on the dressing surface, the dressing method, wherein
when the pad surface is rotated about a center of the pad surface as an axis and the dressing surface itself is rotated about the center as an axis, an approximate curve along an imaginary line of distribution in trajectory density of the pellets passing through the imaginary line in a radial direction from the center of the pad surface is made convex.

Furthermore, this invention can also be defined as follows.

A dresser for a polishing pad surface, the dresser including:
a dressing surface facing the pad surface and pellets arranged on the dressing surface,
when the pad surface is rotated about a center of the pad surface as an axis and the dressing surface itself is rotated about the center as an axis, a maximum value of an approximate curve along an imaginary line of distribution in trajectory density of the pellets passing through the imaginary line in a radial direction from the center of the pad surface exists near a center of the imaginary line.

Furthermore, this invention can also be defined as follows.

A dressing method for dressing a pad surface by a dresser for the polishing pad surface, including:
a dressing surface facing the pad surface and pellets arranged on the dressing surface, the dressing method, wherein
when the pad surface is rotated about a center of the pad surface as an axis and the dressing surface itself is rotated about the center as an axis, a maximum value of an approximate curve along an imaginary line of distribution in trajectory density of the pellets passing through the imaginary line in a radial direction from the center of the pad surface is caused to exist near a center of the imaginary line.

In the dresser of Comparative Example 1, the pellets are unevenly distributed on the outer peripheral side on the dressing surface. On the other hand, in the dresser of Example 1, the pellets are arranged so as to gradually decrease from the center of the dressing surface toward the outside.

This applies also to the dressers of other Examples. Therefore, the invention of the present application can also be defined as follows.

A dresser for a polishing pad surface, the dresser including:
a dressing surface facing the pad surface and pellets arranged on the dressing surface, and
a first grid and a second grid that are imaginary meshes overlapped with the dressing surface, in which the second grid is positioned outside relative to the first grid when viewed from a center of the dressing surface, and
a density of the pellets appearing in the first grid is larger than a density of the pellets appearing in the second grid.

Here, the shape and size of the imaginary mesh can be arbitrarily set, but each grid constituting the mesh is congruent, and at least a part of the pellet is included therein.

The center of the dressing surface preferably coincides with the center of the first grid.

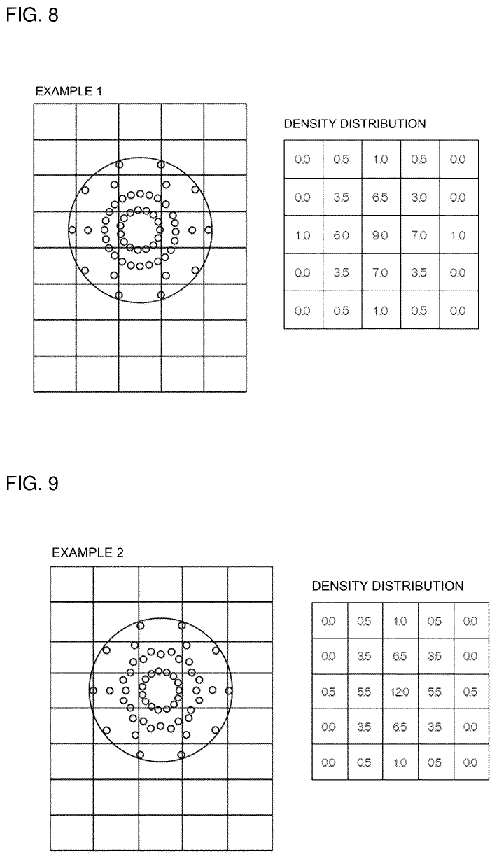

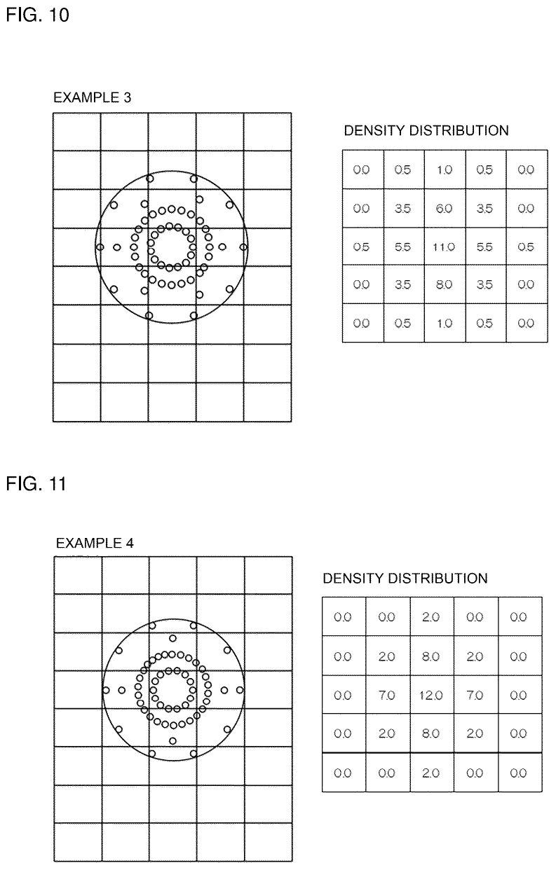

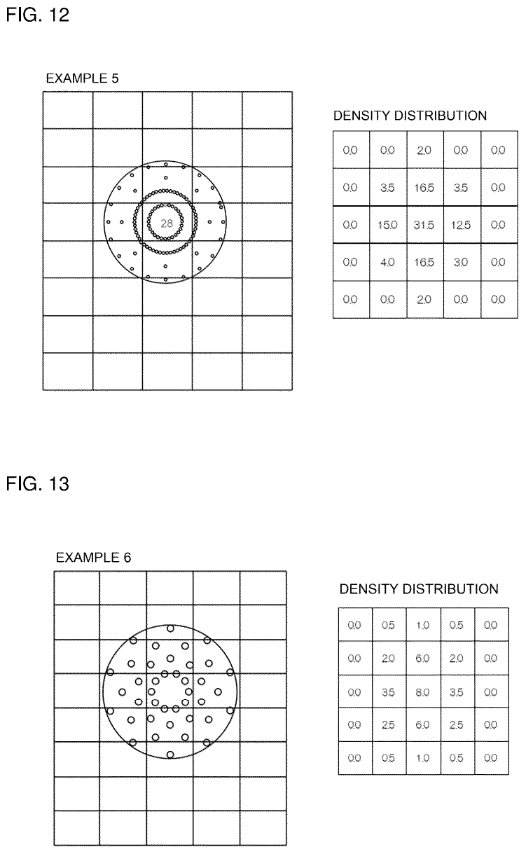

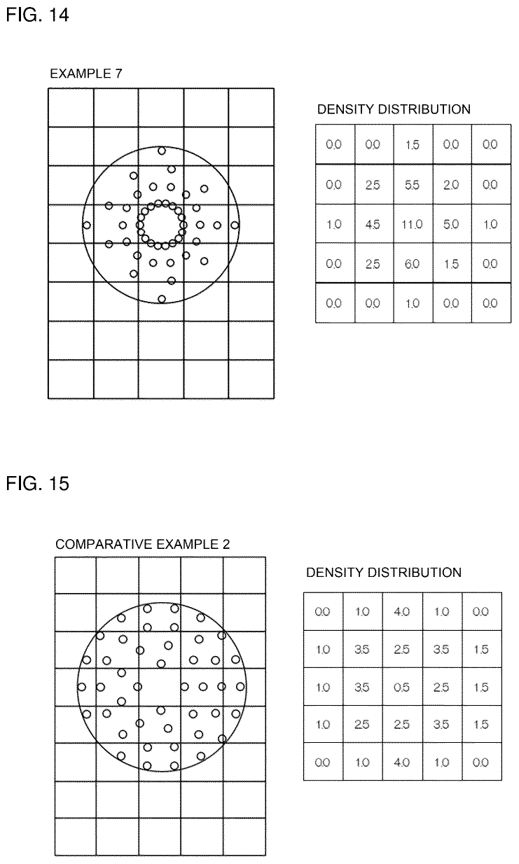

FIGS. 8 to 14 illustrate examples of meshes applied to the dressing surfaces of Examples 1 to 7. A quadrangle grid in the figures is a mesh, a large circle indicates a dressing surface, and a small circle indicates a free end of the pellet. The number sequence on the right of the figure illustrates the number of pellets included in each grid of the mesh. Since the grids are all the same in shape and size, the number of pellets included in the grid refers to the density of the area of the pellets in the grid. In counting of the number of grids, it is assumed that ½ of the area of those crossing the grid exists in each grid.

As illustrated in FIGS. 8 to 14, when a grid (first grid) covering the center of the dressing surface and a grid (second grid) existing continuously with and outside the grid (first grid) are compared in terms of the density of pellets, the density of the former is larger than the density of the latter. Similarly, when the second grid and a grid (third grid) existing continuously with and outside the grid (second grid) are compared in terms of the density of pellets, the density of the former is larger than the density of the latter.

FIG. 15 illustrates an example in which the dressing surface of Comparative Example 2 is applied with a mesh.

In this Comparative Example 2, when a grid (first grid) covering the center of the dressing surface and a grid (second grid) existing continuously with and outside the grid (first grid) are compared in terms of the density of pellets, the density of the former is smaller than the density of the latter.

Since use of the dresser of each Example improves the flatness of the polishing pad, the life of the polishing pad was improved about twice.

An LHA polishing pad (see Japanese Patent No. 5511266) and the dresser of Example 1 were set in a polishing device for a semiconductor substrate, and the polishing work was performed using the dressers of Example 1 and Comparative Example 1 with the dressing time per one time required for the dressing work for regenerating an LHA polishing pad as 30 seconds, and then with polishing the workpiece with the LHA polishing pad for 2 hours as one cycle of the polishing work.

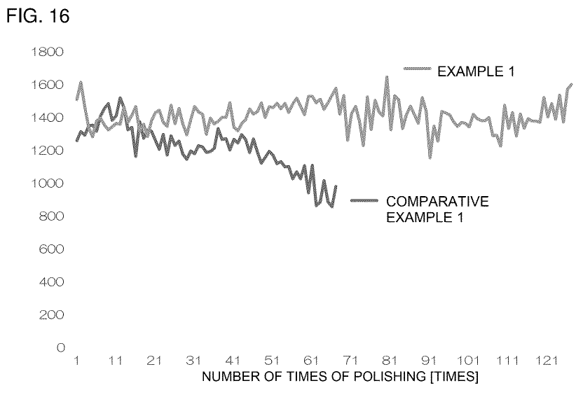

The relationship between the number of times of polishing work (number of cycles) and the polishing rate (nm/hour) is illustrated in FIG. 16. In FIG. 16, the horizontal axis represents the number of times of polishing work, and the vertical axis represents the polishing rate. The polishing rate was obtained from the mean value of thickness changes of a plurality of parts of the LHA polishing pad measured with the dial gauge.

The result of FIG. 16 indicates that the polishing work exceeding 120 cycles becomes possible in the case of using the dresser of Example 1. On the other hand, the polishing rate became unstable before 60 cycles in the case of using the dresser of Comparative Example 1.

That is, it is found that according to the dresser of Example 1, the polishing work can be executed substantially continuously 60 times or more, furthermore 120 times or more without replacing the dresser and the polishing pad at all. In terms of the total dressing time, according to the dresser of Example 1, the polishing work can be executed for 30 minutes or more, furthermore 1 hour or more.

The polishing conditions in the above were as follows.
Workpiece: SiC substrate
Workpiece rotation number: 35 rpm
LHA polishing pad: diameter ¢ 900 mm
Pad rotation number: 35 rpm
Dresser: Example 1
Dresser position: 272 mm
Dressing time per one time required to regenerate polishing pad: 30 seconds

The upper limit of the dressing work time is not particularly limited, but it is necessary to replace the dresser when the flatness required for the workpiece falls below a predetermined value.

This means life improvement of the dresser itself, and the replacement frequency can be reduced.

An increase in the life of the polishing pad and the dresser improves the manufacturing throughput of the workpiece (semiconductor substrate or the like) that is the polishing target.

In this manner, the manufacturing cost of the workpiece manufactured by the process in which the polishing cycle can be repeated twice or more becomes low.

In the above, it can be seen that the dressing time required per one time of dressing work is also reduced. Note that the time required for one time of dressing work when the dresser of the conventional example as in Comparative Example 1 is used sometimes took 60 seconds.

The dresser of each Example can impart high flatness to the polishing pad even if co-rotated to the rotation of the polishing pad. In other words, a mechanism for controlling the rotation number of a turntable of the dresser in the polishing device becomes unnecessary. Therefore, the polishing device becomes inexpensive, and thus the manufacturing cost of the workpiece can be reduced.

From the above, another aspect of this invention can be defined as follows.

A polishing method for polishing a workpiece with a polishing pad containing a polishing material, the polishing method including:
a step of preparing the dresser of the example; and
a dressing step of pressing a dressing surface of the dresser against the pad surface and rotating the dresser and/or the pad, wherein
the pad is an LHA polishing pad, and
a polishing step of polishing a workpiece with the pad having been dressed; wherein
in the dressing step, the dressing work can be executed for 30 minutes or more using an identical dresser.

In the dressing step, the dresser is preferably co-rotated with respect to the pad.

This invention can also be defined as follows.

A method for manufacturing a workpiece, the manufacturing method including:
a step of preparing the dresser of the example;
a dressing step of pressing a dressing surface of the dresser against the pad surface and rotating the dresser and/or the pad; and
a polishing step of polishing the workpiece with the pad having bee dressed, wherein
the pad is an LHA polishing pad, and as the pad, the dressing work using an identical dresser can be executed for 30 minutes or more.

In the dressing step, the dresser is preferably co-rotated with respect to the pad.

This invention is not limited at all to the description of the embodiment of the invention described above. Various modifications are also included in this invention in a range that can be easily conceived by those skilled in the art without departing from the scope of the claims.

### REFERENCE SIGNS LIST

D dresser
P polishing pad
1 holding member
3 pellet
5 dressing surface (pellet support surface)

1. A dresser for a polishing pad surface, the dresser comprising:
a dressing surface having a circular shape with a diameter DCD and facing the pad surface, and pellets arranged on the dressing surface, wherein
the pellets are arranged in circumferential regions with a diameter PCDn, in which the circumferential regions share a center of the dressing surface; and
an area ratio of the pellets arranged in each circumferential region is any one of Type 1, Type 2, and Type 3 in Table 1 below.
TABLE 1

| | PCDn | PCDn/DCD = Rn (%) | Pellet area ratio % |
|---|---|---|---|
| Type 1 | PCD5 | 0 < R5 ≤ 20 | 0 |
| | PCD4 | 20 < R4 ≤ 40 | 30 ± 5 |
| | PCD3 | 40 < R3 ≤ 60 | 45 ± 5 |
| | PCD2 | 60 < R2 ≤ 80 | 10 ± 5 |
| | PCD1 | 80 < R1 < 100 | 15 ± 5 |
| Type 2 | PCD5 | 0 < R5 ≤ 20 | 0 |
| | PCD4 | 20 < R4 ≤ 40 | 25 ± 3 |
| | PCD3 | 40 < R3 ≤ 60 | 25 ± 3 |
| | PCD2 | 60 < R2 ≤ 80 | 25 ± 3 |
| | PCD1 | 80 < R1 < 100 | 25 ± 3 |
| Type 3 | PCD5 | 0 < R5 ≤ 20 | 0 |
| | PCD4 | 20 < R4 ≤ 40 | 40 ± 3 |
| | PCD3 | 40 < R3 ≤ 60 | 31 ± 3 |
| | PCD2 | 60 < R2 < 80 | 20 ± 3 |
| | PCD1 | 80 < R1 < 100 | 9 ± 3 |

2. The dresser according to claim 1, wherein an area ratio of the pellet is the Type 1.

3. A dresser for a polishing pad surface, comprising:
a dressing surface facing the pad surface and pellets arranged on the dressing surface,
when the pad surface is rotated about a center of the pad surface as an axis and the dressing surface itself is rotated about the center as an axis, a variation in trajectory density of the pellets passing through an imaginary line in a radial direction from the center of the pad surface becomes equal to or less than 2000.

4. The dresser according to claim 3, wherein the variation becomes equal to or less than 1500.

5. A dressing method for dressing a pad surface by a dresser for the polishing pad surface, including:
a dressing surface facing the pad surface and pellets arranged on the dressing surface, the dressing method, wherein
when the pad surface is rotated about a center of the pad surface as an axis and the dressing surface itself is rotated about the center as an axis, a variation in trajectory density of the pellets passing through an imaginary line in a radial direction from the center of the pad surface is made equal to or less than 2000.

6. The dressing method according to claim 5, wherein an approximate curve along the imaginary line of distribution of the trajectory densities is convex.

7. The dressing method according to claim 5, wherein a maximum value of an approximate curve along the imaginary line of distribution of the trajectory densities exists near a center of the imaginary line.

8. A polishing method for polishing a workpiece with a polishing pad containing a polishing material, the polishing method comprising:
a step of preparing the dresser according to claim 1; and
a dressing step of pressing a dressing surface of the dresser against the pad surface and rotating the dresser and/or the pad, wherein
the pad is an LHA polishing pad, and
a polishing step of polishing a workpiece with the pad having been dressed, wherein
in the dressing step, the dressing work can be executed for 30 minutes or more using an identical dresser.

9. The polishing method according to claim 8, wherein in the dressing step, the dresser is co-rotated with respect to the pad.

10. A method for manufacturing a workpiece, the manufacturing method comprising:
a step of preparing the dresser according to claim 1;
a dressing step of pressing a dressing surface of the dresser against the pad surface and rotating the dresser and/or the pad; and
a polishing step of polishing the workpiece with the pad having bee dressed, wherein
the pad is an LHA polishing pad, and as the pad, the dressing work using an identical dresser can be executed for 30 minutes or more.

11. The manufacturing method according to claim 10, wherein in the dressing step, the dresser is co-rotated with respect to the pad.
